(19) United States
(12) Patent Application Publication
(10) Pub. No.: US 2009/0107522 A1
(43) Pub. Date: Apr. 30, 2009

(54) SUBSTRATE TREATMENT METHOD AND SUBSTRATE TREATMENT APPARATUS

(76) Inventors: Hiroaki Uchida, Kyoto (JP); Tadashi Maegawa, Kyoto (JP); Seiji Ano, Kyoto (JP)

Correspondence Address: OSTROLENK FABER GERB & SOFFEN, 1180 AVENUE OF THE AMERICAS, NEW YORK, NY, 100368403, US

(21) Appl. No.: 12/255,132

(22) Filed: Oct. 21, 2008

(30) Foreign Application Priority Data
Oct. 30, 2007 (JP) 2007-281985

(51) Int. Cl. C23G 1/02; H01L 21/30

(52) U.S. Cl. 134/3; 118/708

(57) ABSTRACT

An inventive substrate treatment method is performed by a substrate treatment apparatus including a plate having an opposed surface to be kept in opposed spaced relation to one surface of a substrate for treating the substrate with a treatment liquid, and includes: a pre-supply liquid filling step of supplying a pre-supply liquid into a space defined between the one surface of the substrate and the plate through a spout which is provided in the opposed surface in opposed relation to the center of the substrate, and filling the space with the pre-supply liquid, the pre-supply liquid having a smaller contact angle with respect to the substrate and the plate than the treatment liquid; a treatment liquid replacing step of, after a liquid-filled state is established in the space filled with the pre-supply liquid, supplying the treatment liquid into the space to replace the pre-supply liquid present in the space with the treatment liquid while keeping the space in the liquid-filled state; and a treatment liquid contacting step of, after the replacement of the pre-supply liquid, filling the space with the treatment liquid to cause the treatment liquid to contact the one surface of the substrate.

### BACKGROUND OF THE INVENTION

1. Field of the Invention

The present invention relates to a substrate treatment method and a substrate treatment apparatus. Exemplary substrates to be treated include semiconductor wafers, glass substrates for liquid crystal display devices, glass substrates for plasma display devices, glass substrates for FED (Field Emission Display) devices, substrates for optical disks, substrates for magnetic disks, substrates for magneto-optical disks, substrates for photo masks, and ceramic substrates.

2. Description of Related Art

In production processes for semiconductor devices and liquid crystal display devices, a substrate treatment apparatus of a single substrate treatment type is often used for treating a surface of a substrate such as a semiconductor wafer or a glass substrate for a liquid crystal display panel with a treatment liquid. The substrate treatment apparatus includes, for example, a substrate holding member which generally horizontally holds the substrate, a plate to be opposed to the surface of the substrate held by the substrate holding member as being spaced a predetermined minute distance from the surface, and a spout provided in a surface of the plate opposed to the substrate for spouting the treatment liquid (see, for example, Japanese Unexamined Patent Publication No. 8-78368). The treatment liquid spouted from the spout is supplied into a space defined between the surface of the substrate and the plate, so that the space is filled with the treatment liquid. In order to fill the space between the surface of the substrate and the plate with the treatment liquid to establish a liquid-filled state in the space, the treatment liquid is brought into contact with the entire surface of the substrate. Thus, the surface of the substrate is treated with the treatment liquid.

However, a gas-liquid interface is easily formed between the treatment liquid (e.g., deionized water) and air. Therefore, when the space between the surface of the substrate and the plate is filled with the treatment liquid, air originally present in the space is likely to be trapped in the space. As a result, air bubbles are liable to reside in the space filled with the treatment liquid.

The air bubbles prevent the treatment liquid from contacting the surface of the substrate, so that the treatment does not proceed as desired on areas of the substrate on which the air bubbles reside. Therefore, the treatment with the treatment liquid is likely to unevenly proceed within a plane of the substrate.

### SUMMARY OF THE INVENTION

It is an object of the present invention to provide a substrate treatment method and a substrate treatment apparatus which ensure even treatment of one entire surface of a substrate with a treatment liquid while substantially preventing air from being trapped in a space filled with the treatment liquid on the substrate.

A substrate treatment method according to the present invention is performed by a substrate treatment apparatus including a plate having an opposed surface to be kept in opposed spaced relation to one surface of a substrate for treating the substrate with a treatment liquid, the substrate treatment method including: a pre-supply liquid filling step of supplying a pre-supply liquid into a space defined between the one surface of the substrate and the plate through a spout which is provided in the opposed surface of the plate in opposed relation to the center of the substrate, and filling the space between the one surface of the substrate and the plate with the pre-supply liquid, the pre-supply liquid having a smaller contact angle with respect to the substrate and the plate than the treatment liquid; a treatment liquid replacing step of, after a liquid-filled state is established in the space filled with the pre-supply liquid, supplying the treatment liquid into the space between the one surface of the substrate and the plate to replace the pre-supply liquid present in the space with the treatment liquid while keeping the space in the liquid-filled state; and a treatment liquid contacting step of, after the replacement of the pre-supply liquid, filling the space with the treatment liquid to cause the treatment liquid to contact the one surface of the substrate.

A substrate treatment apparatus according to the present invention is configured to treat a substrate with a treatment liquid, the apparatus including: a plate having an opposed surface to be kept in opposed spaced relation to one surface of the substrate and a spout provided in the opposed surface thereof; a pre-supply liquid supplying unit which supplies a pre-supply liquid to the spout, the pre-supply liquid having a smaller contact angle with respect to the substrate and the plate than the treatment liquid; a treatment liquid supplying unit which supplies the treatment liquid into a space defined between the one surface of the substrate and the plate; and a control unit which controls the pre-supply liquid supplying unit to fill the space with the pre-supply liquid to establish a liquid-filled state in the space, and controls the treatment liquid supplying unit to replace the pre-supply liquid present in the space with the treatment liquid to fill the space with the treatment liquid.

Before the one surface of the substrate is brought into contact with the treatment liquid, the liquid-filled state is once established with the space between the one surface of the substrate and the plate being filled with the pre-supply liquid. Since the pre-supply liquid has a smaller contact angle with respect to the substrate and the plate than the treatment liquid, the substrate and the plate are properly wetted with the pre-supply liquid supplied into the space. Therefore, a gas-liquid interface is less liable to be formed between the pre-supply liquid and the ambient air, so that the air is relatively easily movable in the space. Accordingly, air originally present in the space is smoothly expelled from the space by the treatment liquid supplied into the space, so that virtually no air bubbles reside in the space after the liquid-filled state is established in the space filled with the pre-supply liquid.

Thereafter, the pre-supply liquid present in the space is replaced with the treatment liquid with the space kept in the liquid-filled state. Then, the space is filled with the treatment liquid, whereby the substrate is treated with the treatment liquid. Since the pre-supply liquid is replaced with the treatment liquid with the space kept in the liquid-filled state, virtually no air bubbles reside in the space filled with the treatment liquid. Thus, the one entire surface of the substrate is evenly kept in contact with the treatment liquid and, therefore, evenly treated with the treatment liquid.

Examples of the pre-supply liquid include alcohols such as IPA (isopropanol), ethanol and methanol, fluorine-containing solvents such as HFE (hydrofluoroether), and liquids containing surface-activation agents.

The supply of the treatment liquid in the treatment liquid replacing step preferably continuously follows the supply of the pre-supply liquid in the pre-supply liquid filling step. In this case, the pre-supply liquid and the treatment liquid are sequentially supplied into the space. Thus, the space is kept in the liquid-filled state without trapping new air bubbles.

The treatment liquid replacing step may include the step of supplying the treatment liquid into the space between the one surface of the substrate and the plate from the spout through a pipe through which the pre-supply liquid is supplied to the spout. In this case, the pre-supply liquid and the treatment liquid are supplied through the common pipe and spouted into the space, so that the pre-supply liquid is substantially prevented from remaining in the pipe. This prevents contamination of the substrate which may otherwise occur when the pre-supply liquid drips from the pipe.

Further, the treatment liquid supplied into the space does not hinder liquid flow in the space, because the pre-supply liquid and the treatment liquid are supplied from the common spout. Thus, the space is kept in the liquid-filled state without trapping new air bubbles in the treatment liquid replacing step.

At least a part of the plate to be opposed to the one surface of the substrate may be made of quartz. In this case, the plate is further wettable with the pre-supply liquid supplied into the space between the one surface of the substrate and the plate, because the quartz used as a material for at least the part of the plate opposed to the one surface of the substrate is hydrophilic. Thus, the air bubbles can be more reliably removed from the space.

The foregoing and other objects, features and effects of the present invention will become more apparent from the following detailed description of the preferred embodiments with reference to the attached drawings.

### BRIEF DESCRIPTION OF THE DRAWINGS

FIG. 1 is a sectional view schematically showing the construction of a substrate treatment apparatus according to one embodiment of the present invention;

FIG. 2A is a perspective view of a lower substrate holding member;

FIG. 2B is a plan view schematically showing the construction of the lower substrate holding member;

FIG. 3 is a block diagram showing the electrical construction of the substrate treatment apparatus;

FIG. 4 is a flow chart for explaining an exemplary treatment process to be performed by the substrate treatment apparatus; and

FIGS. 5(a) to 5(d) are diagrams for explaining the exemplary treatment process to be performed by the substrate treatment apparatus.

### DETAILED DESCRIPTION OF PREFERRED EMBODIMENTS

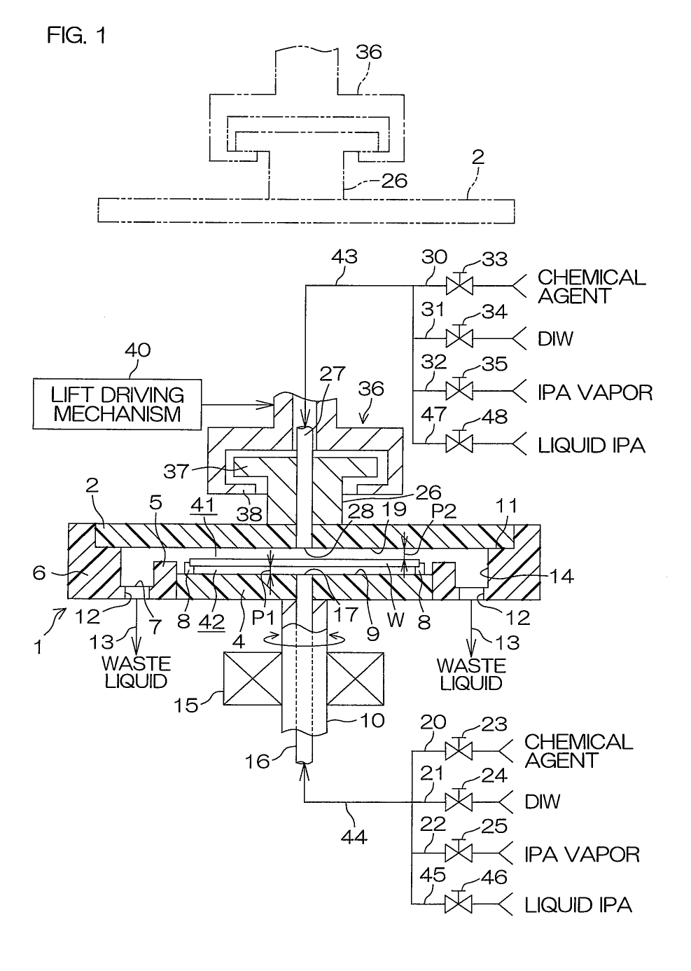

FIG. 1 is a sectional view schematically showing the construction of a substrate treatment apparatus according to one embodiment of the present invention.

The substrate treatment apparatus is of a single substrate treatment type which treats front and back surfaces of a semiconductor wafer W as an exemplary substrate (hereinafter referred to simply as “wafer”) with a treatment liquid. The substrate treatment apparatus includes a lower substrate holding member 1 of a generally cylindrical bottomed shape for holding the wafer W, and an upper plate 2 of a disk shape opposed to the lower substrate holding member 1 above the lower substrate holding member 1. A chemical agent and DIW (deionized water) are used as the treatment liquid for the treatment of the front and back surfaces of the wafer W. Examples of the chemical agent include hydrofluoric acid, buffered hydrofluoric acid (buffered HF, which is a liquid mixture of hydrofluoric acid and ammonium fluoride), SC1 (ammonia-hydrogen peroxide mixture), SC2 (hydrochloric acid/hydrogen peroxide mixture), SPM (sulfuric acid/hydrogen peroxide mixture) and polymer removing liquids.

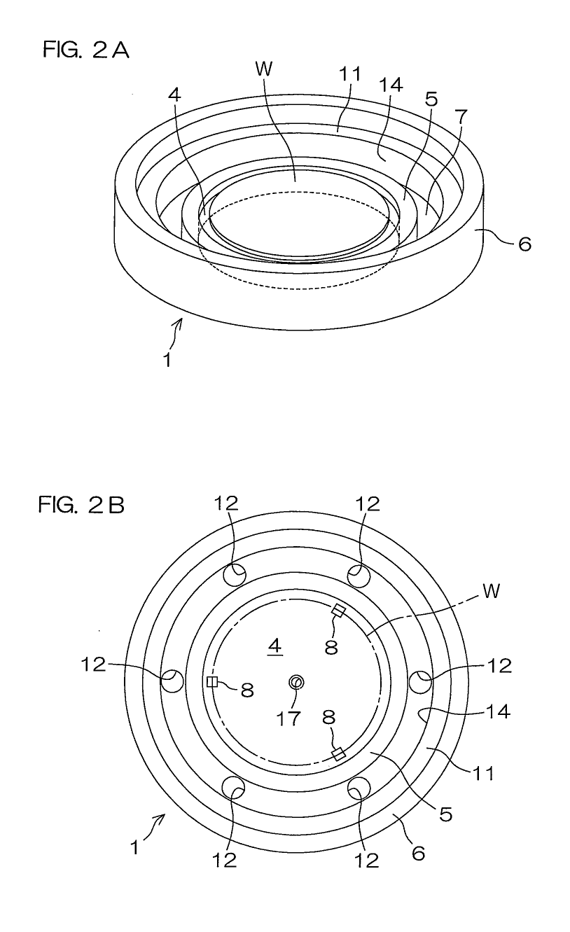

FIG. 2A is a perspective view of the lower substrate holding member 1, and FIG. 2B is a plan view schematically showing the construction of the lower substrate holding member 1. Particularly, FIG. 2A illustrates the lower substrate holding member 1 with the wafer W being held thereon.

Referring to FIGS. 1, 2A and 2B, the lower substrate holding member 1 includes a lower plate portion 4 of a disk shape having a slightly greater diameter than the wafer W, an inner annular portion 5 of a generally cylindrical shape disposed adjacent the lower plate portion 4 as surrounding the lower plate portion 4, an outer annular portion 6 of a generally cylindrical shape surrounding the inner annular portion 5, and an annular connection portion 7 which connects a lower portion of the inner annular portion 5 to a lower portion of the outer annular portion 6.

The lower plate portion 4 has a lower substrate-opposed surface 9 to be opposed to a lower surface of the wafer W held on the lower plate portion 4, and is disposed with its lower substrate-opposed surface 9 facing up. The lower substrate-opposed surface 9 is a generally flat horizontal surface. A plurality of support pins 8 (e.g., three support pins 8) for holding the wafer W are generally equidistantly disposed on a peripheral portion of the lower substrate-opposed surface 9. The lower substrate-opposed surface 9 is opposed to the lower surface of the wafer W held by the plurality of support pins 8 as being spaced a predetermined distance P1 (e.g., 0.5 mm to 2.0 mm) from the lower surface of the wafer W. The lower plate portion 4 is made of quartz.

The inner annular portion 5 has a generally cylindrical shape coaxial with the center axis of a rotation shaft 10 to be described later. The inner annular portion 5 has an upper surface located at substantially the same height level as the wafer W held on the lower plate portion 4.

The outer annular portion 6 has a generally cylindrical shape coaxial with the center axis of the rotation shaft 10 to be described later. The outer annular portion 6 has an annular step 11 provided on an upper edge portion of an inner peripheral surface thereof between the inner and outer annular portions 5 and 6 for receiving a peripheral edge of the upper plate 2. That is, the upper plate 2 is fitted in the annular step 11 to be thereby positioned in a treatment position to be described later. The bottom of the annular step 11 is located at a higher level than the upper surface of the inner annular portion 5.

A drain channel 14 for draining waste liquid such as waste chemical agent is provided on the connection portion 7. The drain channel 14 is an annular channel which is coaxial with a rotation axis of the wafer W (the center axis of the rotation shaft 10 to be described later) and defined by an outer peripheral surface of the inner annular portion 5, an inner peripheral surface of the outer annular portion 6 and an upper surface of the connection portion 7. The connection portion 7 has a plurality of drain holes 12 (e.g., six drain holes 12) equidistantly provided circumferentially about the center axis of the rotation shaft 10 as vertically extending therethrough. Drain pipes 13 extending to a waste liquid treatment facility not shown are respectively connected to the drain holes 12. The inner annular portion 5, the outer annular portion 6 and the connection portion 7 are unitarily formed, for example, of polyvinyl chloride.

The rotation shaft 10 extends vertically, and is connected to a lower surface of the lower plate portion 4. A rotation force is inputted to the rotation shaft 10 from a motor 15.

Further, the rotation shaft 10 is hollow, and a lower surface treatment fluid supply pipe 16 is inserted in the rotation shaft 10. The lower surface treatment fluid supply pipe 16 extends to the lower substrate-opposed surface 9 of the lower plate portion 4, and communicates with a lower spout 17 which opens in a center portion of the lower substrate-opposed surface 9. The lower surface treatment fluid supply pipe 16 is rotatable together with the rotation shaft 10. The lower surface treatment fluid supply pipe 16 is connected to a stationary lower supply pipe 44 via a rotary joint not shown. The lower supply pipe 44 is connected to a lower chemical agent supply pipe 20, a lower DIW supply pipe 21, a lower IPA vapor supply pipe 22 and a lower liquid IPA supply pipe 45.

The chemical agent is supplied to the lower chemical agent supply pipe 20 from a chemical agent supply source. A lower chemical agent valve 23 for permitting and prohibiting the supply of the chemical agent is provided in the lower chemical agent supply pipe 20.

The DIW is supplied to the lower DIW supply pipe 21 from a DIW supply source. A lower DIW valve 24 for permitting and prohibiting the supply of the DIW is provided in the lower DIW supply pipe 21.

IPA vapor is supplied to the lower IPA vapor supply pipe 22 from an IPA vapor supply source. A lower IPA vapor valve 25 for permitting and prohibiting the supply of the IPA vapor is provided in the lower IPA vapor supply pipe 22.

Liquid IPA is supplied as a pre-supply liquid to the lower liquid IPA supply pipe 45 from a liquid IPA supply source. A lower liquid IPA valve 46 for permitting and prohibiting the supply of the liquid IPA is provided in the lower liquid IPA supply pipe 45.

When the lower chemical agent valve 23 is opened with the lower DIW valve 24, the lower IPA vapor valve 25 and the lower liquid IPA valve 46 being closed, the chemical agent from the chemical agent supply source is supplied to the lower spout 17 through the lower chemical agent supply pipe 20, the lower supply pipe 44 and the lower surface treatment fluid supply pipe 16. When the lower DIW valve 24 is opened with the lower chemical agent valve 23, the lower IPA vapor valve 25 and the lower liquid IPA valve 46 being closed, the DIW from the DIW supply source is supplied to the lower spout 17 through the lower DIW supply pipe 21, the lower supply pipe 44 and the lower surface treatment fluid supply pipe 16. When the lower IPA vapor valve 25 is opened with the lower chemical agent valve 23, the lower DIW valve 24 and the lower liquid IPA valve 46 being closed, the IPA vapor from the IPA vapor supply source is supplied to the lower spout 17 through the lower IPA vapor supply pipe 22, the lower supply pipe 44 and the lower surface treatment fluid supply pipe 16. When the lower liquid IPA valve 46 is opened with the lower chemical agent valve 23, the lower DIW valve 24 and the lower IPA vapor valve 25 being closed, the liquid IPA from the liquid IPA supply source is supplied to the lower spout 17 through the lower liquid IPA supply pipe 45, the lower supply pipe 44 and the lower surface treatment fluid supply pipe 16.

The upper plate 2 has a disk shape having a greater diameter than the wafer W, and is made of quartz. The upper plate 2 has an upper substrate-opposed surface 19 to be opposed to the wafer W held on the lower plate portion 4, and is disposed with its upper substrate-opposed surface 19 facing down. The upper substrate-opposed surface 19 is a flat horizontal surface.

A rotation shaft 26 extending coaxially with the rotation shaft 10 is fixed to an upper surface of the upper plate 2. The rotation shaft 26 is hollow, and an upper surface treatment fluid supply pipe 27 is inserted in the rotation shaft 26. The upper surface treatment fluid supply pipe 27 extends to the upper substrate-opposed surface 19 of the upper plate 2, and communicates with an upper spout 28 which opens in a center portion of the upper substrate-opposed surface 19.

The upper surface treatment fluid supply pipe 27 is rotatable together with the rotation shaft 26. The upper surface treatment fluid supply pipe 27 is connected to a stationary upper supply pipe 43 via a rotary joint not shown. The upper supply pipe 43 is connected to an upper chemical agent supply pipe 30, an upper DIW supply pipe 31, an upper IPA vapor supply pipe 32 and an upper liquid IPA supply pipe 47.

The chemical agent is supplied to the upper chemical agent supply pipe 30 from the chemical agent supply source. An upper chemical agent valve 33 for permitting and prohibiting the supply of the chemical agent is provided in the upper chemical agent supply pipe 30.

The DIW is supplied to the upper DIW supply pipe 31 from the DIW supply source. An upper DIW valve 34 for permitting and prohibiting the supply of the DIW is provided in the upper DIW supply pipe 31.

The IPA vapor is supplied to the upper IPA vapor supply pipe 32 from the IPA vapor supply source not shown. An upper IPA vapor valve 35 for permitting and prohibiting the supply of the IPA vapor is provided in the upper IPA vapor supply pipe 32.

The liquid IPA is supplied to the upper liquid IPA supply pipe 47 from the liquid IPA supply source. An upper liquid IPA valve 48 for permitting and prohibiting the supply of the liquid IPA is provided in the upper liquid IPA supply pipe 47.

When the upper chemical agent valve 33 is opened with the upper DIW valve 34, the upper IPA vapor valve 35 and the upper liquid IPA valve 48 being closed, the chemical agent from the chemical agent supply source is supplied to the upper spout 28 through the upper chemical agent supply pipe 30, the upper supply pipe 43 and the upper surface treatment fluid supply pipe 27. When the upper DIW valve 34 is opened with the upper chemical agent valve 33, the upper IPA vapor valve 35 and the upper liquid IPA valve 48 being closed, the DIW from the DIW supply source is supplied to the upper spout 28 through the upper DIW supply pipe 31, the upper supply pipe 43 and the upper surface treatment fluid supply pipe 27. When the upper IPA vapor valve 35 is opened with the upper chemical agent valve 33, the upper DIW valve 34 and the upper liquid IPA valve 48 being closed, the IPA vapor from the IPA vapor supply source is supplied to the upper spout 28 through the upper IPA vapor supply pipe 32, the upper supply pipe 43 and the upper surface treatment fluid supply pipe 27. When the upper liquid IPA valve 48 is opened with the upper chemical agent valve 33, the upper DIW valve 34 and the upper IPA vapor valve 35 being closed, the liquid IPA from the liquid IPA supply source is supplied to the upper spout 28 through the upper liquid IPA supply pipe 47, the upper supply pipe 43 and the upper surface treatment fluid supply pipe 27.

The rotation shaft 26 is supported from the above by a lift member 36 which is movable up and down. The rotation shaft 26 has an annular flange 37 provided on an outer peripheral surface thereof as projecting radially outward from an upper end portion thereof. The lift member 36 includes an annular support plate 38 which surrounds the rotation shaft 26 below the flange 37. An inner peripheral edge of the support plate 38 has a smaller diameter than an outer peripheral edge of the flange 37. The rotation shaft 26 is supported by the lift member 36 with an upper surface of the support plate 38 in engagement with a lower surface of the flange 37.

A lift driving mechanism 40 for moving up and down the lift member 36 is connected to the lift member 36. By driving the lift driving mechanism 40, the upper plate 2 fixed to the rotation shaft 26 is moved up and down between the treatment position at which the upper plate 2 fixed to the rotation shaft 26 is located in the vicinity of the upper surface of the wafer W held on the lower plate portion 4 (as indicated by a solid line in FIG. 1) and a retracted position at which the upper plate 2 is significantly retracted above the lower plate portion 4 (as indicated by a two-dot-and-dash line in FIG. 1).

With the upper plate 2 moved down to the treatment position, the wafer W is treated with the treatment liquid. At the treatment position, the upper plate 2 is opposed to the upper surface of the wafer W held on the lower plate portion 4 as being spaced a predetermined distance P2 (e.g., 1.0 mm) from the upper surface of the wafer W.

When the lift driving mechanism 40 is driven to move down the upper plate 2 from the retracted position to the treatment position, the peripheral edge portion of the upper plate 2 is received by the annular step 11 of the outer annular portion 6. When the lift member 36 is thereafter further moved down, the flange 37 is disengaged from the support member 38. Thus, the rotation shaft 26 and the upper plate 2 are detached from the lift member 36 and supported by the lower substrate holding member 1. Therefore, the upper plate 2 is rotatable together with the lower substrate holding member 1 at the treatment position. By inputting a rotative drive force to the rotation shaft 26 from the motor 15 with the wafer W being held on the lower plate portion 4, the upper plate 2, the lower plate portion 4 and the wafer W are rotated about a vertical axis.

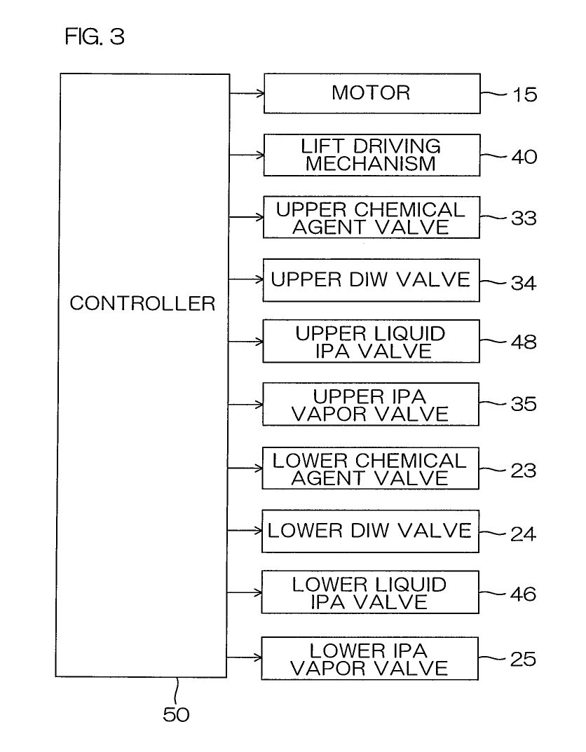

FIG. 3 is a block diagram showing the electrical construction of the substrate treatment apparatus.

The substrate treatment apparatus includes a controller 50 including a microcomputer.

The controller 50 is connected to the motor 15, the lift driving mechanism 40, the upper chemical agent valve 33, the upper DIW valve 34, the upper IPA vapor valve 35, the lower chemical agent valve 23, the lower DIW valve 24, the lower IPA vapor valve 25, and the like.

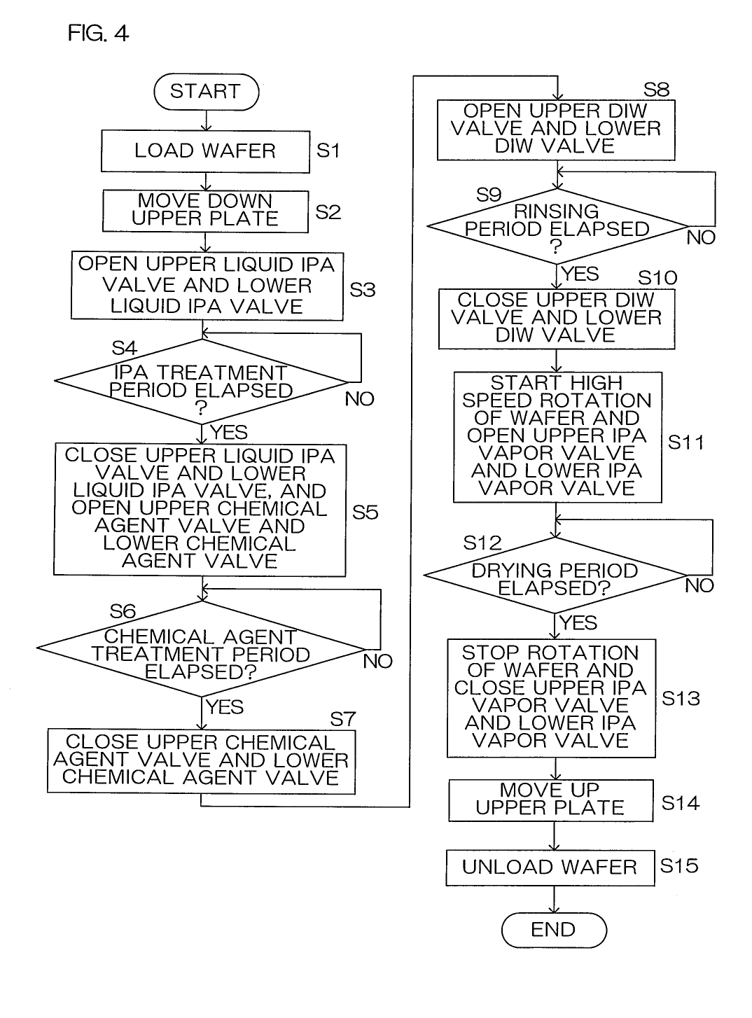

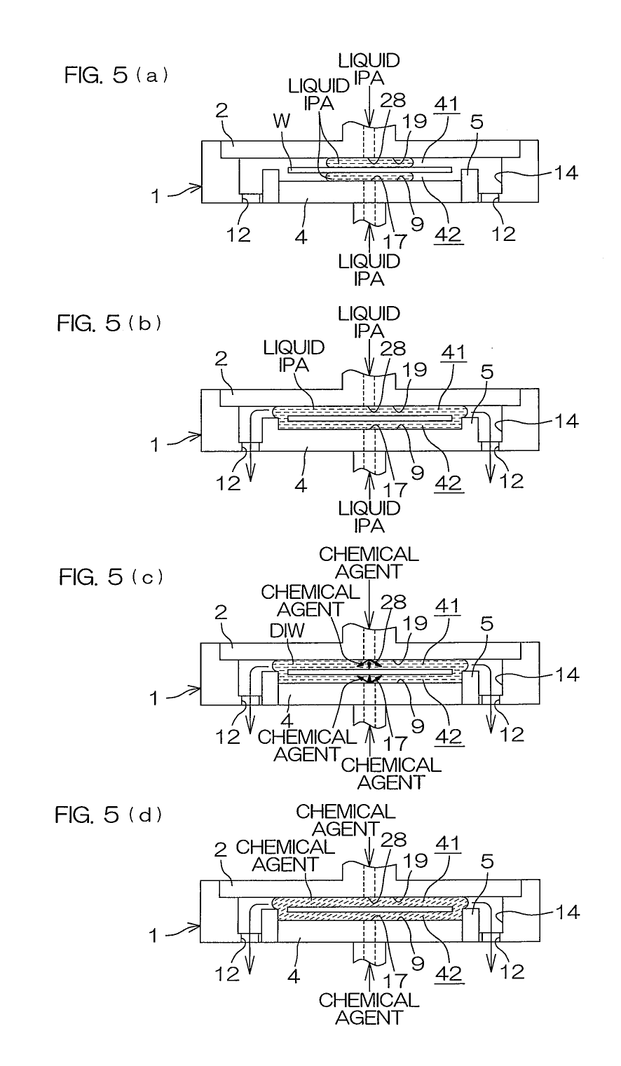

FIG. 4 is a flow chart for explaining an exemplary treatment process to be performed by the substrate treatment apparatus. FIGS. 5(a) to 5(d) are diagrams for explaining the exemplary treatment process to be performed by the substrate treatment apparatus. In the substrate treatment process to be described below, a hydrophobic silicon wafer as an example of the wafer W is cleaned.

The wafer W to be treated is loaded into the substrate treatment apparatus by a transport robot not shown, and held on the lower plate portion 4 of the lower substrate holding member 1 with its front surface facing up (Step S1). When the wafer W is loaded, the upper plate 2 is located at the retracted position.

With the wafer W being held on the lower plate portion 4, the controller 50 drives the lift driving mechanism 40 to move down the upper plate 2 to the treatment position so that the upper substrate-opposed surface 19 is brought into opposed relation to the upper surface of the wafer W (Step S2).

After the upper plate 2 is moved down to the treatment position, the controller 50 opens the upper liquid IPA valve 48 and the lower liquid IPA valve 46 (Step S3). Thus, the liquid IPA is supplied to the upper supply pipe 43 and the lower supply pipe 44 from the upper liquid IPA supply pipe 47 and the lower liquid IPA supply pipe 45, respectively. The liquid IPA supplied into the upper supply pipe 43 is spouted from the upper spout 28 through the upper surface treatment fluid supply pipe 27. Further, the liquid IPA supplied into the lower supply pipe 44 is spouted from the lower spout 17 through the lower surface treatment fluid supply pipe 16. The liquid IPA has a relatively small contact angle with respect to a silicon material and a quartz material (i.e., the liquid IPA has a smaller contact angle with respect to the silicon material and the quartz material than the chemical agent and the DIW). The liquid IPA from the upper spout 28 is supplied to an upper treatment space 41 defined between the upper surface of the wafer W and the upper substrate-opposed surface 19 of the upper plate 2, and spread radially from the upper spout 28 in the upper treatment space 41. Further, the liquid IPA from the lower spout 17 is supplied to a lower treatment space 42 defined between the lower surface of the wafer W and the lower substrate-opposed surface 9 of the lower plate portion 4, and spread radially from the lower spout 17 in the lower treatment space 42 (see FIG. 5(a)). The wafer W, the upper plate 2 and the lower plate portion 4 are properly wetted with the liquid IPA supplied to the upper treatment space 41 and the lower treatment space 42, because the liquid IPA has a relatively small contact angle with respect to the wafer W, the upper plate 2 and the lower plate portion 4. Particularly, the upper plate 2 and the lower plate portion 4 which are each made of the hydrophilic quartz are more wettable with the liquid IPA. Accordingly, a gas-liquid interface is less liable to be formed between the liquid IPA and the ambient air, so that the air has a relatively high mobility in the upper treatment space 41 and the lower treatment space 42. Therefore, air originally present in the upper treatment space 41 and the lower treatment space 42 is expelled from the spaces 41, 42 by the liquid IPA supplied into the upper treatment space 41 and the lower treatment space 42.

The liquid IPA is continuously spouted from the upper spout 28 and the lower spout 17, whereby a space defined between the upper plate 2 and the lower plate portion 4 is filled with the liquid IPA. Thus, a liquid-filled state is established in the upper treatment space 41 and the lower treatment space 42 filled with the liquid IPA (see FIG. 5(b)). Virtually no air bubbles are present in the upper treatment space 41 and the lower treatment space 42 which are filled with the liquid IPA to be kept in the liquid-filled state.

After a lapse of a predetermined IPA treatment period (e.g., 1 to 10 seconds) during which the upper treatment space 41 and the lower treatment space 42 are filled with the liquid IPA to be kept in the liquid-filled state (YES in Step S4), the controller 50 closes the upper liquid IPA valve 48 and the lower liquid IPA valve 46, and opens the upper chemical agent valve 33 and the lower chemical agent valve 23 (Step S5). Thus, the supply of the liquid IPA to the upper supply pipe 43 is stopped, and the chemical agent is supplied into the upper supply pipe 43 from the upper chemical agent supply pipe 30. Further, the supply of the liquid IPA to the lower supply pipe 44 is stopped, and the chemical agent is supplied into the lower supply pipe 44 from the lower chemical agent supply pipe 20. At this time, the upper chemical agent valve 33 and the lower chemical agent valve 23 are opened generally simultaneously with the closing of the upper liquid IPA valve 48 and the lower liquid IPA valve 46. Therefore, the upper treatment space 41 and the lower treatment space 42 are still kept in the liquid-filled state during the switching from the liquid IPA to the chemical agent.

The chemical agent supplied to the upper supply pipe 43 is spouted from the upper spout 28 through the upper surface treatment fluid supply pipe 27 (see FIG. 5(c)). The chemical agent supplied to the upper treatment space 41 from the upper spout 28 is mixed with the liquid IPA and spread in the upper treatment space 41 kept in the liquid-filled state. Further, the chemical agent supplied to the lower supply pipe 44 is spouted from the lower spout 17 through the lower surface treatment fluid supply pipe 16 (see FIG. 5(c)). The chemical agent supplied into the lower treatment space 42 from the lower spout 17 is mixed with the liquid IPA and spread in the lower treatment space 42 kept in the liquid-filled state.

Then, the liquid IPA present in the upper treatment space 41 and the lower treatment space 42 is gradually replaced with the chemical agent with the upper treatment space 41 and the lower treatment space 42 kept in the liquid-filled state. As a result, the concentrations of the chemical agent in the liquid IPA in the upper treatment space 41 and the lower treatment space 42 are increased. As the chemical agent is supplied into the upper treatment space 41 and the lower treatment space 42, the spaces 41, 42 are filled with the chemical agent and, finally, the liquid-filled state is established in the upper treatment space 41 and the lower treatment space 42.

The chemical agent is spouted into the upper treatment space 41 through the pipes 43, 27 through which the liquid IPA has flowed, and spouted into the lower treatment space 42 through the pipes 44, 16 through which the liquid IPA has flowed. Therefore, the liquid IPA is prevented from remaining in the upper supply pipe 43, the upper surface treatment fluid supply pipe 27, the lower supply pipe 44 and the lower surface treatment fluid supply pipe 16. This prevents the contamination of the wafer W with the liquid IPA which may otherwise occur when the liquid IPA is dripped from the pipes 43, 27, 44, 16 toward the wafer W.

Since the chemical agent is spouted into the upper treatment space 41 and the lower treatment space 42 from the upper spout 28 and the lower spout 17, respectively, from which the liquid IPA has been spouted, there is virtually no possibility that the chemical agent supplied into the spaces 41, 42 prevents the flow of the liquid IPA in the spaces 41, 42.

Thereafter, the chemical agent is continuously spouted from the upper spout 28 and the lower spout 17, whereby the upper treatment space 41 and the lower treatment space 42 are kept filled with the chemical agent. Thus, the upper and lower surfaces of the wafer W are kept in contact with the chemical agent, and cleaned with the chemical agent (see FIG. 5(d)). The chemical agent overflows from the upper treatment space 41 and the lower treatment space 42, and is drained to the waste liquid treatment facility not shown sequentially through a space defined between the upper substrate-opposed surface 19 of the upper plate 2 and the upper surface of the inner annular portion 5, the drain channel 14, the drain holes 12 and the drain pipes 13.

The upper treatment space 41 and the lower treatment space 42 are relatively narrow. Therefore, the upper treatment space 41 and the lower treatment space 42 can be filled with a smaller amount of the chemical agent. This reduces the consumption of the chemical agent.

After a lapse of a predetermined chemical agent treatment period (e.g., 30 seconds) (YES in Step S6), the controller 50 closes the upper chemical agent valve 33 and the lower chemical agent valve 23 to stop the supply of the chemical agent from the upper spout 28 and the lower spout 17 (Step S7).

Then, the controller 50 opens the upper DIW valve 34 and the lower DIW valve 24 to spout the DIW from the upper spout 28 and the lower spout 17 (Step S8). Thus, the chemical agent present in the upper treatment space 41 and the lower treatment space 42 is gradually replaced with the DIW with the upper treatment space 41 and the lower treatment space 42 kept in the liquid-filled state. Finally, the upper treatment space 41 and the lower treatment space 42 are filled with the DIW.

Thereafter, the DIW is continuously spouted from the upper spout 28 and the lower spout 17, whereby the upper treatment space 41 and the lower treatment space 42 are kept filled with the DIW. Thus, the upper and lower surfaces of the wafer W are kept in contact with the DIW, so that the chemical agent adhering to the upper and lower surfaces of the wafer W is rinsed away with the DIW. The DIW overflows from the upper treatment space 41 and the lower treatment space 42, and is drained to the waste liquid treatment facility not shown sequentially through the space between the upper substrate-opposed surface 19 of the upper plate 2 and the upper surface of the inner annular portion 5, the drain channel 14, the drain holes 12 and the drain pipes 13.

After a lapse of a predetermined rinsing period (e.g., 60 seconds) (YES in Step S9), the controller 50 closes the upper DIW valve 34 and the lower DIW valve 24 to stop the supply of the DIW from the upper spout 28 and the lower spout 17 (Step S10).

Then, the controller 50 opens the upper IPA vapor valve 35 and the lower IPA vapor valve 25 to spout the IPA vapor from the upper spout 28 and the lower spout 17 (Step S11). Further, the controller 50 controls the motor 15 to rotate the wafer W at a predetermined drying speed (e.g., a higher speed on the order of 2500 rpm) (Step S11). Thus, the DIW adhering to the upper and lower surfaces of the wafer W is spun off by a centrifugal force, whereby the wafer W is dried.

In this drying step, the upper substrate-opposed surface 19 of the upper plate 2 and the lower substrate-opposed surface 9 of the lower plate portion 4 are closely opposed to the upper and lower surfaces of the wafer W, respectively, so that the upper and lower surfaces of the wafer W are isolated from the external atmosphere. By supplying the IPA vapor to the upper treatment space 41 and the lower treatment space 42, the DIW adhering to the upper and lower surfaces of the wafer W is replaced with IPA, and the upper and lower surfaces of the wafer W are dried due to the volatility of the IPA vapor. Thus, the upper and lower surfaces of the wafer W are quickly dried with no DIW mark left on the lower surface of the wafer W in the drying step.

After a lapse of a predetermined drying period (e.g., 30 seconds) (YES in Step S12), the controller 50 controls the motor 15 to stop the rotation of the lower substrate holding member 1, and closes the upper IPA vapor valve 35 and the lower IPA vapor valve 25 to stop the supply of the IPA vapor from the upper spout 28 and the lower spout 17 (Step S13).

After the rotation of the lower substrate holding member 1 is stopped, the controller 50 drives the lift driving mechanism 40 to move up the upper plate 2 toward the retracted position (Step S14). Thereafter, the treated wafer W is unloaded by the transport robot not shown (Step S15).

According to this embodiment, as described above, the liquid-filled state is once established in the upper treatment space 41 and the lower treatment space 42 filled with the liquid IPA before the chemical agent is supplied to the wafer W. The wafer W, the upper plate 2 and the lower plate portion 4 are properly wetted with the liquid IPA supplied into the upper treatment space 41 and the lower treatment space 42, because the liquid IPA has a relatively small contact angle with respect to the wafer W, the upper plate 2 and the lower plate portion 4. Therefore, a gas-liquid interface is less liable to be formed between the liquid IPA and the ambient air, so that the air has a relatively high mobility in the upper treatment space 41 and the lower treatment space 42. Accordingly, the air present in the upper treatment space 41 and the lower treatment space 42 is expelled by the liquid IPA supplied into the spaces 41, 42, so that virtually no air bubbles are present in the upper treatment space 41 and the lower treatment space 42 kept in the liquid-filled state.

With the upper treatment space 41 and the lower treatment space 42 kept in the liquid-filled state, the liquid IPA present in the spaces 41, 42 is replaced with the chemical agent. Thus, the upper treatment space 41 and the lower treatment space 42 are filled with the chemical agent, whereby the wafer W is treated with the chemical agent. Since the upper treatment space 41 and the lower treatment space 42 are kept in the liquid-filled state during the replacement of the liquid IPA with the chemical agent, virtually no air bubbles are present in the spaces 41, 42 filled with the chemical agent. Thus, the entire upper and lower surfaces of the wafer W are evenly kept in contact with the chemical agent and, therefore, evenly treated with the chemical agent.

Further, the upper plate 2 and the lower plate portion 4 are made of the hydrophilic quartz and, therefore, further wettable with the liquid IPA supplied into the upper treatment space 41 and the lower treatment space 42. Thus, the air bubbles are reliably removed from the upper treatment space 41 and the lower treatment space 42.

While one embodiment of the present invention has thus been described, the invention may be embodied in other ways. In the embodiment described above, the liquid IPA is used as the pre-supply liquid by way of example. Instead of the liquid IPA, an alcohol solvent such as ethanol or methanol may be used as the pre-supply liquid. Alternatively, a fluorine-containing solvent such as HFE (hydrofluoroether) or a liquid containing a surface active agent may be used as the pre-supply liquid.

Where liquid HFE is used as the pre-supply liquid, the upper treatment space 41 and the lower treatment space 42 are first filled with the liquid HFE to be kept in the liquid-filled state. When the chemical agent is supplied into the upper treatment space 41 and the lower treatment space 42 from the upper spout 28 and the lower spout 17, the chemical agent does not intermingle with the liquid HFE, but pushes out the liquid HFE to spread in the spaces 41, 42. Then, the upper treatment space 41 and the lower treatment space 42 are filled with the chemical agent.

Further, the liquid IPA present in the upper treatment space 41 and the lower treatment space 42 may be replaced with the DIW but not with the chemical agent. In this case, the chemical agent is supplied into the upper treatment space 41 and the lower treatment space 42 after the replacement with the DIW, whereby the spaces 41, 42 are filled with the chemical agent. Thus, the wafer W is treated with the chemical agent.

In the embodiment described above, the chemical agent and the DIW are used as the treatment liquid by way of example. However, only the DIW may be used as the treatment liquid. In this case, the DIW is used instead of the chemical agent in Steps S5 to S7, and Steps S8 to S10 for the rinsing may be omitted. Not only the DIW but also functional water such as carbonated water, ionized water, ozonized water, reductive water (hydrogen water) or magnetic water may be used as the treatment liquid.

During the supply of the liquid IPA, at least one of the upper plate 2 and the lower plate portion 4 may be rotated. Thus, even if air bubbles are present in the upper treatment space 41 and the lower treatment space 42, the air bubbles can be removed.

The material for the upper plate 2 and the lower plate portion 4 is not limited to the hydrophilic quartz, but may be a hydrophobic material such as polyvinyl chloride. Even in this case, the upper treatment space 41 and the lower treatment space 42 are filled with the pre-supply liquid such as the liquid IPA to be kept in the liquid-filled state before the supply of the treatment liquid, whereby the contact angle with respect to the surfaces of the upper plate 2 and the lower plate portion 4 is reduced. Therefore, the air bubbles present in the spaces 41, 42 can be removed by a centrifugal force.

While the present invention has been described in detail by way of the embodiment thereof, it should be understood that the embodiment is merely illustrative of the technical principles of the present invention but not limitative of the invention. The spirit and scope of the present invention are to be limited only by the appended claims.

This application corresponds to Japanese Patent Application No. 2007-281985 filed in the Japanese Patent Office on Oct. 30, 2007, the disclosure of which is incorporated herein by reference in its entirety.

What is claimed is:

1. A substrate treatment method to be performed by a substrate treatment apparatus including a plate having an opposed surface to be kept in opposed spaced relation to one surface of a substrate for treating the substrate with a treatment liquid, the substrate treatment method comprising:
a pre-supply liquid filling step of supplying a pre-supply liquid into a space defined between the one surface of the substrate and the plate through a spout which is provided in the opposed surface of the plate in opposed relation to a center of the substrate, and filling the space between the one surface of the substrate and the plate with the pre-supply liquid, the pre-supply liquid having a smaller contact angle with respect to the substrate and the plate than the treatment liquid;
a treatment liquid replacing step of, after a liquid-filled state is established in the space filled with the pre-supply liquid, supplying the treatment liquid into the space between the one surface of the substrate and the plate to replace the pre-supply liquid present in the space with the treatment liquid while keeping the space in the liquid-filled state; and
a treatment liquid contacting step of, after the replacement of the pre-supply liquid, filling the space with the treatment liquid to cause the treatment liquid to contact the one surface of the substrate.

2. A substrate treatment method as set forth in claim 1, wherein the supply of the treatment liquid in the treatment liquid replacing step continuously follows the supply of the pre-supply liquid in the pre-supply liquid filling step.

3. A substrate treatment method as set forth in claim 1, wherein the treatment liquid replacing step includes the step of supplying the treatment liquid into the space between the one surface of the substrate and the plate from the spout through a pipe through which the pre-supply liquid is supplied to the spout.

4. A substrate treatment apparatus for treating a substrate with a treatment liquid, the apparatus comprising:
a plate having an opposed surface to be kept in opposed spaced relation to one surface of the substrate and a spout provided in the opposed surface thereof;
a pre-supply liquid supplying unit which supplies a pre-supply liquid to the spout, the pre-supply liquid having a smaller contact angle with respect to the substrate and the plate than the treatment liquid;
a treatment liquid supplying unit which supplies the treatment liquid into a space defined between the one surface of the substrate and the plate; and
a control unit which controls the pre-supply liquid supplying unit to fill the space with the pre-supply liquid to establish a liquid-filled state, and controls the treatment liquid supplying unit to replace the pre-supply liquid present in the space with the treatment liquid to fill the space with the treatment liquid.

5. A substrate treatment apparatus as set forth in claim 4, wherein at least a part of the plate to be opposed to the one surface of the substrate is made of quartz.
